(19) United States
(12) Patent Application Publication
(10) Pub. No.: US 2015/0289398 A1
(43) Pub. Date: Oct. 8, 2015

(54) DISPLAY DEVICE

(71) Applicant: SHARP KABUSHIKI KAISHA, Osaka (JP)

(72) Inventor: Kenji Takase, Osaka (JP)

(73) Assignee: Sharp Kabushiki Kaisha, Osaka (JP)

(21) Appl. No.: 14/438,329

(22) PCT Filed: Oct. 29, 2013
(86) PCT No.: PCT/JP2013/079262

§ 371 Date: Apr. 24, 2015

(30) Foreign Application Priority Data
Oct. 30, 2012 (JP) 2012-238893

(51) Int. Cl. H05K 5/02; H05K 5/03; H05K 5/00; B32B 3/30; B32B 7/08

(52) U.S. Cl. CPC H05K 5/0208; B32B 3/30; B32B 7/08; H05K 5/0017; H05K 5/03; B32B 2457/20

(57) ABSTRACT

A display device includes a first cover member that is provided with a first frame surrounding a peripheral edge of a front surface of a display unit, a second cover member that is disposed on the front surface side of the first cover member and that is provided with a second frame that overlaps with the first frame, engaging protrusions that protrude from the front surface of the first frame or a rear surface of the second frame, and engaging recesses that are formed on a rear surface of the second frame, and that the engaging protrusions engage.

### TECHNICAL FIELD

The present invention relates to a display device.

### BACKGROUND ART

A display device such as a liquid crystal display device includes a display unit in which a front surface of the device is a display surface, a cabinet that has an opening in the front surface thereof and surrounds peripheral edges of the front surface of the display unit, and a cover that is disposed on the front surface of the cabinet and covers peripheral edges of the opening. With this display device, the opening serves as a display region in which a video, an image, or the like is displayed, and peripheral portions of the display unit serve as a region in which video is not displayed, i.e., the so-called frame region.

At least one of the cover and the cabinet is a resin molded body, and there have been cases in which, due to molding errors, attachment has been difficult or there has been instability after attachment (shifting, wobbling, or the like occurring). Accordingly, Japanese Patent Application Laid-Open Publication No. 2008-83562 describes a display device that has a simple structure and suppresses attachment anomalies caused by molding errors.

In the display device described in Japanese Patent Application Laid-Open Publication No. 2008-83562, a groove provided with engaging portions is formed in a face opposing one of a periphery of the opening or a portion of the cover opposing the periphery of the opening, and protrusions provided with engaged portions that engage with the engaging portions are provided on another peripheral edge. Furthermore, the protrusions are inserted into the groove and the engaging portions are caused to engage the engaged portions, thereby attaching the cover to the cabinet.

By forming the engaging portions in the opposing face in this manner, the engaging portions securely engage the engaged portions even if molding errors occur in the cabinet or the cover, and therefore the cover does not readily fall off the cabinet.

In recent years, demand for making the frame region in display devices smaller (so-called frame narrowing) has grown. By performing frame narrowing, an outer shape of the display device can be made smaller, and waste can also be eliminated while achieving a lighter weight.

### RELATED ART DOCUMENT

### Patent Document

Patent Document 1: Japanese Patent Application Laid-Open Publication No. 2008-83562

### SUMMARY OF THE INVENTION

### Problems to be Solved by the Invention

However, the display device described in Japanese Patent Application Laid-Open Publication No. 2008-83562 is configured such that the groove is formed in the frame region and the protrusions are inserted into the groove, and therefore when frame narrowing is performed, a distance to an edge of the cabinet or the cover in which the groove is formed becomes shorter, and there is a risk that obtaining sufficient securing strength will become difficult.

Furthermore, if the frame region of the display device in Japanese Patent Application Laid-Open Publication No. 2008-83562 is made smaller, positioning precision of the groove and the protrusions must be high, making manufacturing of the cabinet and the cover proportionately more laborious and time-consuming.

Accordingly, the present invention has as an object to provide a display device that reduces a non-display region in which video is not displayed and suppresses movement and falling off of constituent members with a simple structure, thereby making it possible to increase reliability of the device.

### Means for Solving the Problems

To achieve this object, the present invention provides a display device including a first cover member having a first frame that surrounds a periphery of a front surface of a display unit; a second cover member having a second frame disposed on a front surface side of the first cover member and overlapping the first frame; an engaging protrusion that protrudes from a front surface of the first frame or a rear surface of the second frame; and an engaging recess formed in a surface that faces the front surface of the first frame or the rear surface of the second frame where the engaging protrusion is protruding, the engaging protrusion engaging the engaging recess.

With this configuration, the engaging protrusion and the engaging recess is formed in a portion where the first cover member and the second cover member overlap, that is, a portion that are not visible to an observer, being a configuration in which the first cover member and the second cover member are combined by causing the engaging protrusion and the engaging recess to engage in a forward-and-back direction. Therefore, an outside portion of the display region (the so-called frame region) can be made smaller than in a conventional display device in which the second cover member is formed on an outside of the first cover member or vice-versa.

A display device with a large display region can thus be installed in a small installation location (greater freedom of installation location), and unneeded frame region can be made smaller, which is useful in making the display device smaller and lighter.

In the aforementioned configuration, it is also possible for the engaging protrusion to be arranged in a straight line on a periphery of the first frame or the second frame.

In the aforementioned configuration, it is also possible for the engaging protrusion to be shifted in position in a direction orthogonal to an arrangement direction thereof, with the straight line therebetween.

In the aforementioned configuration, it is also possible for the engaging protrusion to be inclined with respect to a surface from which the engaging protrusion protrudes.

In the aforementioned configuration, it is also possible for the engaging protrusion to have, at a tip thereof, a curved portion that curves outward, and for the engaging recess to have a fitting portion in which the curved portion fits.

In the aforementioned configuration, it is also possible for the first frame and the second frame each to be a rectangular frame, and for the engaging protrusion to be formed on at least two of four sides of the first frame or the second frame.

In the aforementioned configuration, it is also possible for the first frame and the second frame to be a rectangular frame body, and for the engaging protrusion to be formed in two side portions of the first frame or the second frame. Note that if formed in two side portions, the engaging protrusion is preferably formed on opposing sides. Furthermore, if the engaging protrusion is formed in two side portions or three side portions, the engaging protrusion is preferably formed at least in a side portion that is located in a top portion. Furthermore, it is also possible for the engaging protrusion to be formed in all four side portions.

Note that with the aforementioned configuration, in a case of a configuration in which the engaging protrusion is formed in multiple side portions, it is possible for the engaging protrusion incline in a same direction or to incline towards an outer peripheral side of the display device. Furthermore, it is also possible for the engaging protrusion to be formed such that a direction of inclination of some of the engaging protrusions is different.

Furthermore, if the engaging protrusion is formed inclined, the angles of inclination may all be the same, and it is also possible for engaging protrusions with different angles of inclination to be included. Furthermore, it is possible to use a configuration in which the engaging recesses that the engaging protrusions engage have the same angle of inclination as the angle of inclination of the engaging protrusions, and it is also possible to change the angle of inclination enough to allow engaging with the engaging protrusions.

In the aforementioned configuration, it is also possible for the first cover member to be a bezel that holds the display unit, and for the second cover member to be a lens cover having a lens on side edges thereof.

In the aforementioned configuration, it is also possible for the display unit to be a light-emitting unit that emits planar light from a front surface thereof.

### Effects of the Invention

With the present invention, a display device which reduces a non-display region in which video is not displayed and suppresses movement and falling off of constituent members with a simple structure, thereby making it possible to increase reliability, can be provided.

### BRIEF DESCRIPTION OF THE DRAWINGS

FIG. 1 is an exploded oblique view of one example of a display device according to the present invention.

FIG. 2 is a front view of a cabinet used in the display device according to the present invention.

FIG. 3 is a rear view of a cover in the display device according to the present invention.

FIG. 4 is a lateral cross-sectional view of the display device according to the present invention.

FIG. 5 is an enlarged cross-sectional view of a state in which the cover of the display device according to the present invention has been removed.

FIG. 6 is a lateral cross-sectional view of the display device according to the present invention.

FIG. 7 is an enlarged cross-sectional view of a state in which the cover of the display device according to the present invention has been removed.

FIG. 8 is a front view of a cabinet used in yet another example of a display device according to the present invention.

FIG. 9 is an enlarged cross-sectional view of a state in which the cover of yet another example of a display device according to the present invention has been removed.

FIG. 10 is a front view of a cabinet used in yet another example of a display device according to the present invention.

FIG. 11 is an enlarged cross-sectional view of a state in which the cover of another example of a display device according to the present invention has been removed.

FIG. 12 is an enlarged cross-sectional view of a state in which the cover of yet another example of a display device according to the present invention has been removed.

FIG. 13 is a lateral cross-sectional view of a state in which the cover of the display device shown in FIG. 12 has been removed.

FIG. 14 is a view showing a state in which the cover of yet another example of a display device according to the present invention has been removed.

FIG. 15 is a lateral cross-sectional view of a state in which the cover of the display device shown in FIG. 14 has been removed.

FIG. 16 is a lateral cross-sectional view of a state in which the cover of yet another example of a display device according to the present invention has been removed.

### DETAILED DESCRIPTION OF EMBODIMENTS

### Embodiment 1

Embodiments of the present invention are described below with reference to the drawings.

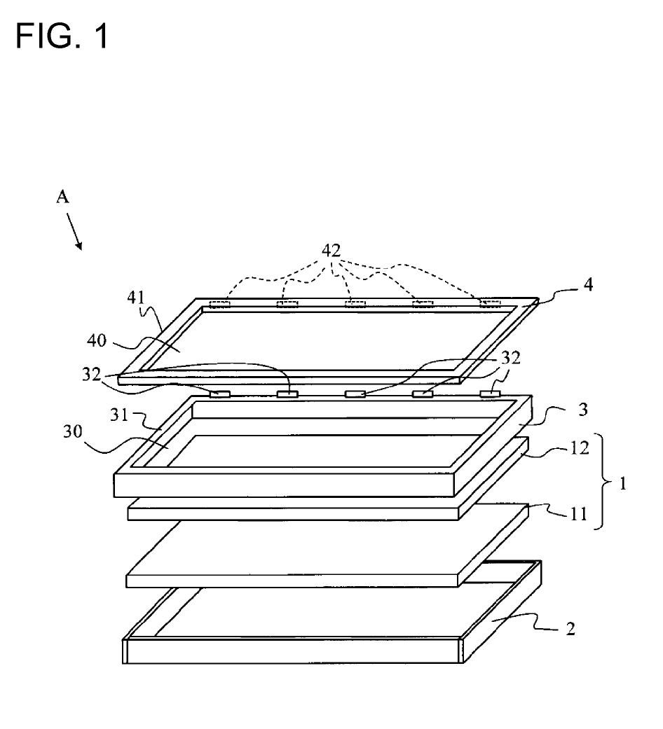

FIG. 1 is an exploded oblique view of one example of a display device according to the present invention. As shown in FIG. 1, a display device A includes a display unit 1 (display unit) that displays video, a chassis 2 that covers a rear surface of the display unit 1, a cabinet 3 (first cover member) that encircles peripheral edges of a front surface of the display unit 1, and a cover 4 (second cover member) that is disposed further forward on the cabinet 3.

The display unit 1 includes a display surface that has a front-viewing rectangular shape and displays video forward. The display unit 1 includes a backlight 11 that emits planar light towards the front surface, and a liquid crystal panel 12 that is disposed on the front surface of the backlight 11.

The backlight 11 is an edge-lit backlight constituted by a light source, a light guide plate, and an optical sheet (not shown in the drawings). The backlight 11 is attached to the chassis 2. Note that the backlight 11 is not limited to this, and while there are also cases in which a direct-lit backlight or an EL backlight are adopted in which a light source is arranged opposite a liquid crystal panel, these too are attached to the chassis 2, similar to the edge-lit type. The liquid crystal panel 12 has a display surface that displays video to a front surface side, and, when planar light from the backlight 11 passes through, adjusts a ratio of the light passing through to displays video on the display surface.

A display device in which the backlight 11 and the liquid crystal panel 12 are combined serves as the display unit 1, but this is not a limitation, and it is also possible to use a self-illuminating display device, such as an EL (organic EL) panel, for example.

The chassis 2 is a bottom box member formed by bending metal plates, and is disposed so as to cover the rear surface of the display unit 1. The cabinet 3 is a member that is disposed on the front surface side of the display unit 1 and presses on peripheral edges of the display unit 1. The cabinet 3 is a frame-shaped member having an opening 30 that is a rectangular through-hole in a central portion.

The display unit 1 is supported by the chassis 2 and the cabinet 3, the rear surface side thereof being pressed by the chassis 2 and the front surface side peripheral edges being pressed by the cabinet 3. The cover 4 is used as a front surface side outer housing of the display device A. Like the cabinet 3, the cover 4 has an opening 40 in a central portion. Details and attachment of the cabinet 3 and the cover 4 are described below, with reference to the drawings. Note that in the following description, the same display unit 1 and the same chassis 2 of the display device are used, and therefore repetitive explanations are omitted.

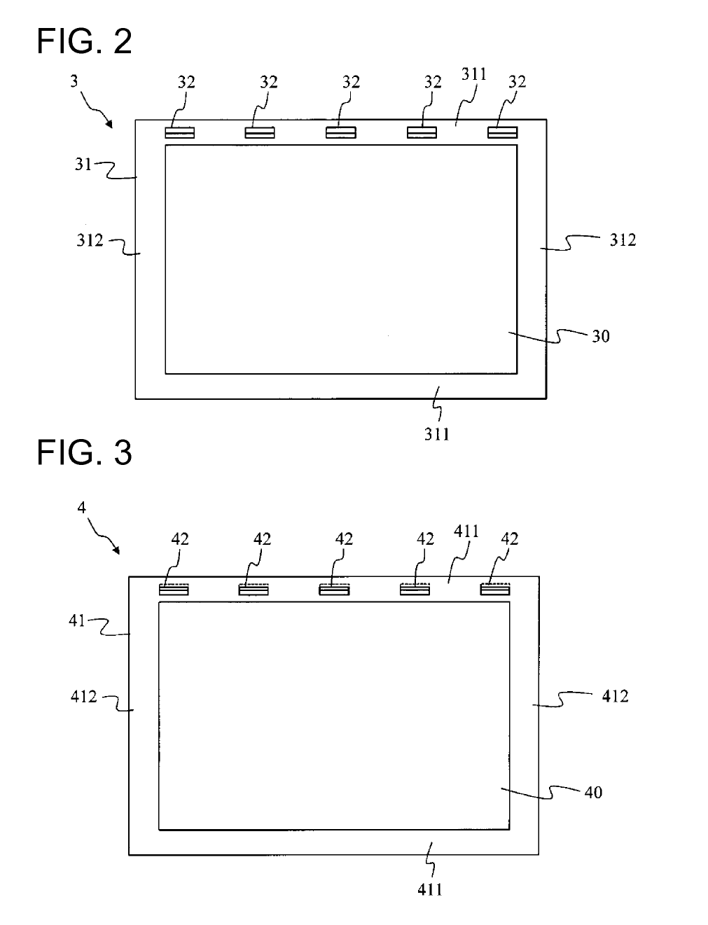

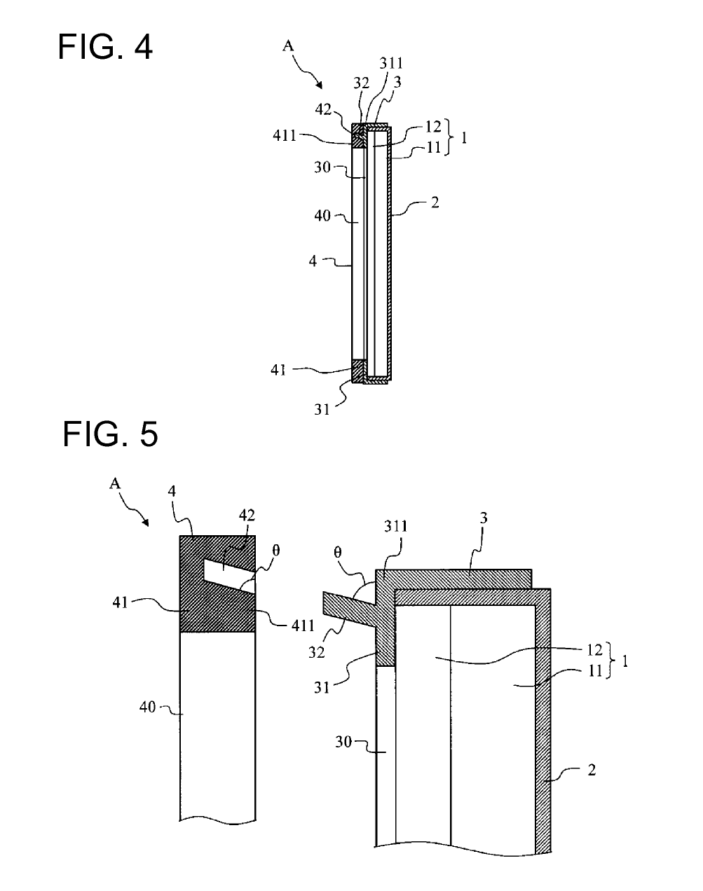

A detailed description of the display device according to the present invention is given, with reference to the drawings. FIG. 2 is a front view of the cabinet used in the display device according to the present invention, FIG. 3 is a rear view of the cover in the display device according to the present invention, FIG. 4 is a lateral cross-sectional view of the display device according to the present invention, and FIG. 5 is an enlarged cross-sectional view of a state in which the cover of the display according to the present invention has been removed. Note that the vertical direction in FIGS. 2 to 5 coincides with up and down when the display device A is installed in an installation location. In the following description, “up” and “down” are based on the state in FIGS. 2 to 5.

The cabinet 3 is an integral resin molded body. The cabinet 3 has a frame that presses on the peripheral edges of the front surface of the display unit 1 and covers side face portions of the display unit 1 (side faces of the chassis 2 inside which the display unit 1 is provided). The cabinet 3 has a main body 31 (first frame) that includes long side portions 311 and short side portions 312 that surround the opening 30, and engaging protrusions 32 that protrude towards an outer periphery side of the cabinet 3, inclined at an angle of inclination θ (0°<θ<90°) relative to the front surface. Furthermore, as shown in FIG. 2, five of the engaging protrusions 32 are provided and are disposed so as to be arranged in a line parallel to a lengthwise direction of the long side portions 311. The engaging protrusions 32 have a square shape or rectangular shape, and of the pair of parallel sides, one pair is parallel to the lengthwise direction of the long side portions 311.

Note that a number of the engaging protrusions 32 is not limited to five. Furthermore, in the cabinet 3 shown in FIG. 2, lengths of the lengthwise direction of the long side portions 311 of the five engaging protrusions 32 are equal, but this is not a limitation, and it is also possible for engaging protrusions 32 having different lengths to be provided. Furthermore, distances between adjacent engaging protrusions 32 are equal, but this is not a limitation, and it is also possible to dispose the engaging protrusions 32 so as to have different distances depending on the location. The number, lengths, and arrangement spacing of the engaging protrusions 32 are set so as to be able to engage with engaging recesses 42, described below, that are formed on the cover 4, and securely hold the cover 4.

The cover 4 is an integral resin molded body. The cover 4 has a flat shape that has an opening in a central portion. As shown in FIG. 3, the cover 4 has a main body 41 (second frame) that includes long side portions 411 and short side portions 412 that surround an opening 40, and the engaging recesses 42 that are holes formed in a rear surface of one of the long side portions 411. The engaging recesses 42 are holes into which the engaging protrusions 32 formed in the cabinet 3 are inserted, and are formed in locations corresponding to the engaging protrusions 32. Furthermore, because a configuration is used in which the cover 4 is attached to the cabinet 3 by inserting the engaging protrusions 32 in the engaging recesses 42, the engaging recesses 42 are such that the bottom side thereof has a recessed hole shape that is inclined by the angle of inclination θ towards the outer peripheral side of the cover 4 (see FIG. 5).

As shown in FIG. 4, the cover 4 is attached to the front surface side of the cabinet 3 so as to overlap the cabinet 3 when viewed from the front. The opening 30 of the cabinet 3 and the opening 40 of the cover 4 serve as windows (display regions) for viewing a video display surface of the display unit 1. Therefore, centers of the opening 30 and the opening 40 overlap when the cabinet 3 and the cover 4 are disposed in an overlapping manner. Note that the main body 31 of the cabinet 3 is preferably not visible at this time. Therefore, the opening 30 is preferably the same size as the opening 40 or slightly larger. Note that in the embodiments of the present invention, the opening 30 and the opening 40 have identical shapes and sizes when viewed from the front.

The cabinet 3 covers a front surface side peripheral edge of the display unit 1, and covers side faces of the chassis 2 on which the display unit 1 is disposed. A well-known method is used for affixing the chassis 2 and the cabinet 3, and details are omitted. The display unit 1 and the chassis 2 are affixed to the rear surface side of the cabinet 3. The cover 4 is then attached to the front surface side of the cabinet 3 to the rear surface side of which the display unit 1 and the chassis 2 are affixed. At this time, the engaging protrusions 32 of the cabinet 3 are inserted into the engaging recesses 42 of the cover 4. By completely inserting the engaging protrusions 32 into the engaging recesses 42, the cover 4 overlaps with the cabinet 3 in a front view (see FIG. 4).

This is described in more detail as follows. First, the long side portion 411 on the side of the cover 4 on which the engaging recesses 42 are formed is brought close to the cabinet 3, and tips of the engaging protrusions 32 are inserted into the engaging recesses 42. Next, the long side portion 411 on the side of the cover 4 opposite where the engaging recesses 42 are formed is brought close to the cabinet 3, and the engaging protrusions 32 move into the bottoms of the engaging recesses 42. The cover 4 is thus attached to the cabinet 3. Note that the engaging protrusions 32 and the engaging recesses 42 can also be used as positioning members that position the cabinet 3 and the cover 4.

The display device A is ordinarily used in a state in which the cabinet 3 is horizontally long and upright. By then disposing the cabinet 3 such that the engaging protrusions 32 are on the upper long side portion 311, the engaging protrusions 32 are tilted upward. By attaching the cover 4 to the cabinet 3 such that the engaging protrusions 32 are inserted into the engaging recesses 42 of the cover 4, the cover 4 is weighted downward by its own weight, and the engaging protrusions 32 enter into the bottom of the engaging recesses 42 and are engaged. The cover 4 is thus disposed so as not to shift towards the front surface side of the cabinet 3.

Specifically, by installing the display device A such that the engaging protrusions 32 of the cabinet 3 are in the top portion and engaging the engaging protrusions 32 with the engaging recesses 42, the cover 4 can be attached to the cabinet 3 stably, without falling or wobbling.

The display device A is configured such that the engaging protrusions 32 protrude towards the front surface side of the cabinet 3, are inserted into the engaging recesses 42 that are formed on the rear surface side of the cover 4, and are engaged, the cover 4 thus being attached to the cabinet 3. Specifically, an engaged portion formed by the engaging protrusions 32 and the engaging recesses 42 is formed in a portion where the cabinet 3 and the cover 4 overlap, and therefore problems relating to strength (deformation or breaking) do not readily occur even if a width when viewed from the front of the long side portions 311 or the short side portions 312 of the cabinet 3 or the long side portions 411 or the short side portions 412 of the cover 4 is made smaller. The region outside the display region, the so-called frame region, can thus be made smaller in the display device A without changing the size of the display region (the opening).

Furthermore, by forming the engaging protrusions 32 and the engaging recesses 42 in the top portion of the display device A, a downward force acts on the cover 4 due to its own weight when the cover 4 is attached to the cabinet 3, and the engaging protrusions 32 move into the bottom of the engaging recesses 42 due to this self-weight force, and therefore the cover 4 does not readily come off.

By using the display device A of the above configuration, limitation of a location where the display device A is installed (size, position, etc.) does not readily apply, and even in cases where limitations of the installation location exist, the display device A, in which a displayed video is large, can be installed, etc. Furthermore, frames that are unrelated to video display of the display device A can be made smaller, and therefore unnecessary material can be reduced, making a lighter weight possible.

Note that the engaging protrusions 32 and the engaging recesses 42 are inclined at the same angle of inclination 0, but it is also possible to make the angle of inclination of the engaging protrusions 32 and the engaging recesses 42 different angles, within an extent whereby the engaging protrusions 32 and the engaging recesses 42 can engage. By changing the angle of inclination of the engaging protrusions 32 and the engaging recesses 42 the engaging protrusions 32 can be pressed against the engaging recesses 42, a strength of affixing between the cabinet 3 and the cover 4 thereby being able to be raised.

Moreover, in the above embodiment, the engaging protrusions 32 and the engaging recesses 42 are inclined, but it is also possible for the engaging protrusions 32 and the engaging recesses 42 not to be inclined; that is, for the engaging protrusions 32 to be perpendicular to the front surface of the long side portions 311 and for the engaging recesses 42 to be perpendicular to the rear surface of the long side portions 411, as long as the cover 4 can be attached to the cabinet 3 in a manner so as not to fall or shift.

Furthermore, in the above embodiment, the cabinet 3 is a resin molded body, but may also be a machined (e.g., pressed, etc.) metal plate. In that case, the engaging protrusions 32 may be formed by lancing or may be an extrusion molded body. Furthermore, a cabinet 3 which has been formed by machining a metal plate may be used in the following embodiments.

Note that in the following description, engaging protrusions and engaging recesses are formed at least in an upper side portion of the display device, unless otherwise stated.

### Embodiment 2

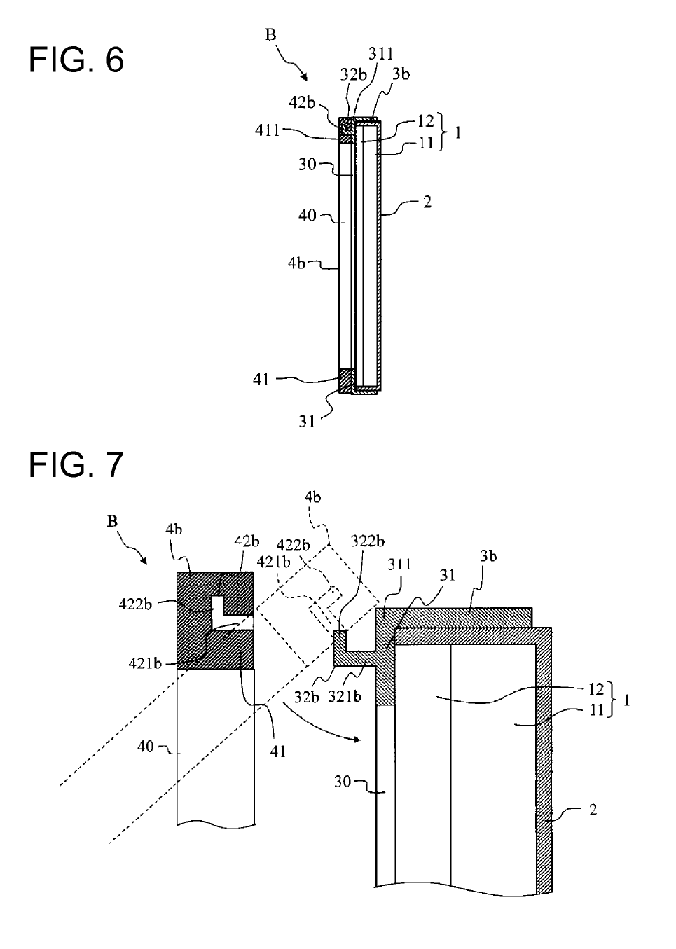

A detailed description of another example of a display device according to the present invention is described, with reference to the drawings. FIG. 6 is a cross-sectional view of a display device according to the present invention, and FIG. 7 is an enlarged cross-sectional view of a state in which a cover of a display device according to the present invention has been removed. As shown in FIG. 6, a display device B has the same configuration as the display device A shown in FIG. 2, etc., aside from engaging protrusions 32b of a cabinet 3b and engaging recesses 42b of a cover 4b differing. Therefore, portions of the display device B which are substantially the same as the display device A are given the same reference characters, and detailed descriptions of the same parts are omitted.

As shown in FIGS. 6 and 7, the cabinet 3b has the engaging protrusions 32b on one front surface of long side portions 311 of a main body 31. The engaging protrusions 32b have protrusions 321b and bent portions 322b that are bent from tips of the protrusions 321b. The protrusions 321b and the bent portions 322b are formed integrally. The bent portions 322b are bent toward an outer peripheral side of the cabinet 3b, and the bent portions 322b are parallel to a front surface of the cabinet 3b. Note that the bent portions 322b need not necessarily be parallel to the front surface of the cabinet 3b.

Furthermore, a rear surface of the cover 4b has, in locations overlapping with the engaging protrusions 32b, the engaging recesses 42b that are recessed holes having a shape so as to allow insertion of the engaging protrusions 32b when the cover 4b is disposed on the front surface side of the cabinet 3b. The engaging recesses 42b have vertical holes 421b that are formed near a surface of the cover 4b and fitting portions 422b that are formed from the deepest portions of the vertical holes 421b and bent toward an outer peripheral side of the cover 4b. The fitting portions 422b have a shape into which the bent portions 322b of the engaging protrusions 32b are to be disposed.

As shown in FIG. 7, the engaging protrusions 32b are formed on the long side portions 311, which are the upper side when the display device B is installed in an upright state. Furthermore, when the engaging protrusions 32b are inserted into the engaging recesses 42b, the cover 4b is securely attached to the cabinet 3b. Furthermore, the engaging protrusions 32b are such that the bent portions 322b are formed on the tips of the protrusions 321b, and are prevented from slipping out of the engaging recesses 42b by the bent portions 322b being inserted into the fitting portions 422b.

Note that with the display device B shapes of the engaging protrusions 32b and the engaging recesses 42b are configured so as to allow the engaging protrusions 32b to be inserted into the engaging recesses 42b by inserting the tip portions of the bent portions 322b into the vertical holes 421b and causing the engaging protrusions 32b and (or) the engaging recesses 42b to undergo elastic deformation. For example, the protrusions 321b and the bent portions 322b of the engaging protrusions 32b are formed so as to allow elastic deformation. Furthermore, the bent portions 322b are inserted into the vertical holes 421b while being caused to undergo elastic deformation, and when the cover 4b is turned and moved downward, the protrusions 321b and the bent portions 322b are caused to undergo elastic deformation and the bent portions 322b are pushed into the fitting portions 422b.

The cover 4b can be securely attached to the cabinet 3b by engaging the engaging protrusions 32b with the engaging recesses 42b in this manner. Furthermore, engagement between the engaging protrusions 32b and the engaging recesses 42b is strong as the engaging protrusions 32b and the engaging recesses 42b are configured so as to be engaged after the engaging protrusions 32b and (or) the engaging recesses 42b undergo elastic deformation. This can minimize separation of the cover 4b from the cabinet 3b even if, for example, the display device B falls over, is hit by an object, or otherwise sustains a shock, and an upward force acts on the cover 4b.

Furthermore, the shapes of the engaging protrusions 32b and the engaging recesses 42b are not limited to the aforementioned shapes. For example, the engaging protrusions 32b and the engaging recesses 42b may also be shaped such that protrusions 321b are tilted and an angle formed with the bent portions 322b exceeds 90°, and may also be formed such that an angle between the vertical holes 421b and the fitting portions 422b exceeds 90°. Thus formed, insertion of the engaging protrusions 32b and the engaging recesses 42b becomes easier, and moreover an amount of elastic deformation during engagement can be reduced, facilitating attachment.

Furthermore, a vertical width of the vertical holes 421b of the engaging recesses 42b may be the same or larger than a length of the bent portions 322b. Thus formed, the engaging protrusions 32b can easily be inserted into the engaging recesses 42b, and engagement is simple. Note that even with this configuration, the cover 4b does not readily shift upward, as the bent portions 322b are bent upward.

Other features are the same as in the display device A described in Embodiment 1.

### Embodiment 3

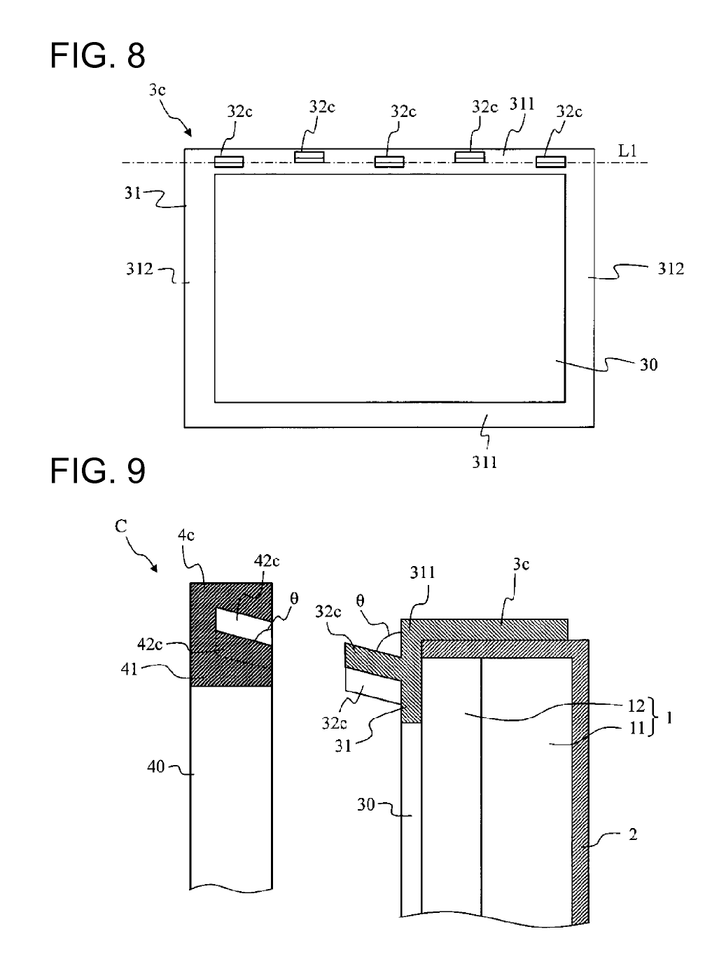

Yet another example of a display device according to the present invention is described, with reference to the drawings. FIG. 8 is a front view of a cabinet used in yet another example of a display device according to the present invention, and FIG. 9 is an enlarged cross-sectional view of a state in which a cover of yet another example of a display device according to the present invention has been removed.

A display device C according to the present invention has the same configuration as the display device A, aside from an arrangement of engaging protrusions 32c of a cabinet 3c and engaging recesses 42c of a cover 4c differing; substantially identical parts are given the same reference characters, and detailed descriptions of identical parts are omitted. Furthermore, shapes of individual ones of the engaging protrusions 32b and the engaging recesses 42b have the same shapes as the shapes of the engaging protrusions 32 and the engaging recesses 42 of the display device A, and details of those shapes are omitted.

As shown in FIGS. 8 and 9, five of the engaging protrusions 32c are arranged in a lengthwise direction of a long side portion 311 on a front surface of the long side portion 311 of a main body 31 of a cabinet 3c. To describe this in detail, adjacent ones of the engaging protrusions 32c are disposed in an alternating arrangement towards an outer peripheral side of the cabinet 3c and an opening 30 side, on either side of a line extending in a lengthwise direction of the long side portions 311 (hereafter sometimes called a center line).

Furthermore, the engaging recesses 42c formed on the cover 4c are similarly such that adjacent engaging recesses 42c are disposed in an alternating arrangement on the outer peripheral side and an opening 40 side, on either side of a line extending in a lengthwise direction of long side portions 411. Note that because the engaging recesses 42c are holes into which the engaging protrusions 32c are inserted, the engaging recesses 42c are formed in positions overlapping with the engaging protrusions 32c when the cover 4c is disposed overlaying a front surface of the cabinet 3c.

Specifically, with the display device C, the engaging protrusions 32c and the engaging recesses 42c into which the engaging protrusions 32c are inserted are disposed along the center line, and adjacent ones are disposed in an alternating manner on either side of the center line. Shifting after the cover 4c is attached to the cabinet 3c can thus be minimized, allowing the cover 4c to be attached securely to the cabinet 3c.

Other features are the same as in the display device A described in Embodiment 1.

### Embodiment 4

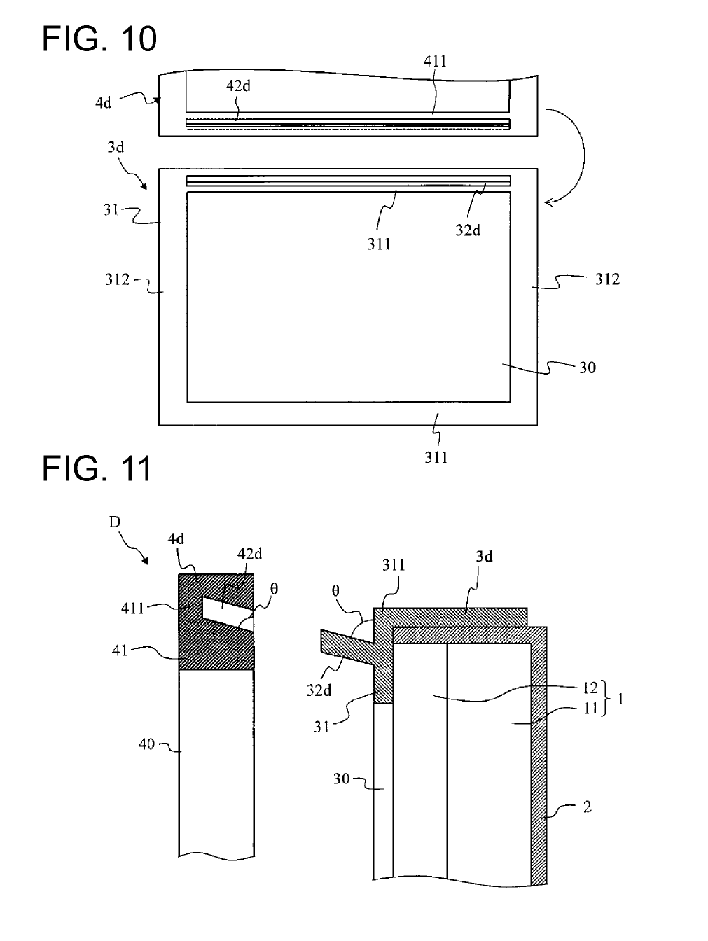

A detailed description of another example of a display device according to the present invention is described, with reference to the drawings. FIG. 10 is a front view of a cabinet used in yet another example of a display device according to the present invention, and FIG. 11 is an enlarged cross-sectional view of a state in which a cover of yet another example of a display device according to the present invention has been removed. Note that FIG. 10 shows part of a cover 4d.

A display device D according to the present invention has the same configuration as the display device A, aside from an arrangement of an engaging protrusion 32d of a cabinet 3d and an engaging recess 42d of the cover 4d differing; substantially identical parts are given the same reference characters, and detailed descriptions of identical parts are omitted.

As shown in FIG. 10, the engaging protrusion portion 32d is formed in a front surface of long side portions 311 of a main body 31 of the cabinet 3d. The engaging protrusion 32d has an elongated protruding shape that extends in a lengthwise direction of the long side portions 311. The engaging protrusion 32d is formed shorter than a length of the cabinet 3d. For example, a length of the engaging protrusion 32d can be made identical to a length connecting the five engaging protrusions 32 formed in the cabinet 3.

Furthermore, as shown in FIG. 11, in the cover 4d, the engaging recess 42d formed with a size and shape so as to allow insertion of the engaging protrusion 32d is formed in a rear surface of a main body 40. The engaging recess 42d is a recessed hole into which the engaging protrusion 32d is to be inserted, and the engaging recess 42d is a recessed groove that extends in a lengthwise direction of main body 41 long side portions 411.

Specifically, with the display device D, the engaging protrusion 32d is formed long and linearly, and therefore compared to one which is divided up, stress does not readily become concentrated even if a load acts on the cover 4d, and thus the engaging protrusion 32d does not readily break. An affixing strength when the cover 4d is attached to the cabinet 3d can thus be raised. Note that the cover 4d can also be attached to the cabinet 3 by forming the engaging recess 42d of the cover 4d in a shape so as to allow insertion of all of the five engaging protrusions 32 of the cabinet 3, making it possible to generalize use of the cover 4d.

Other features are the same as in the display device A described in Embodiment 1.

### Embodiment 5

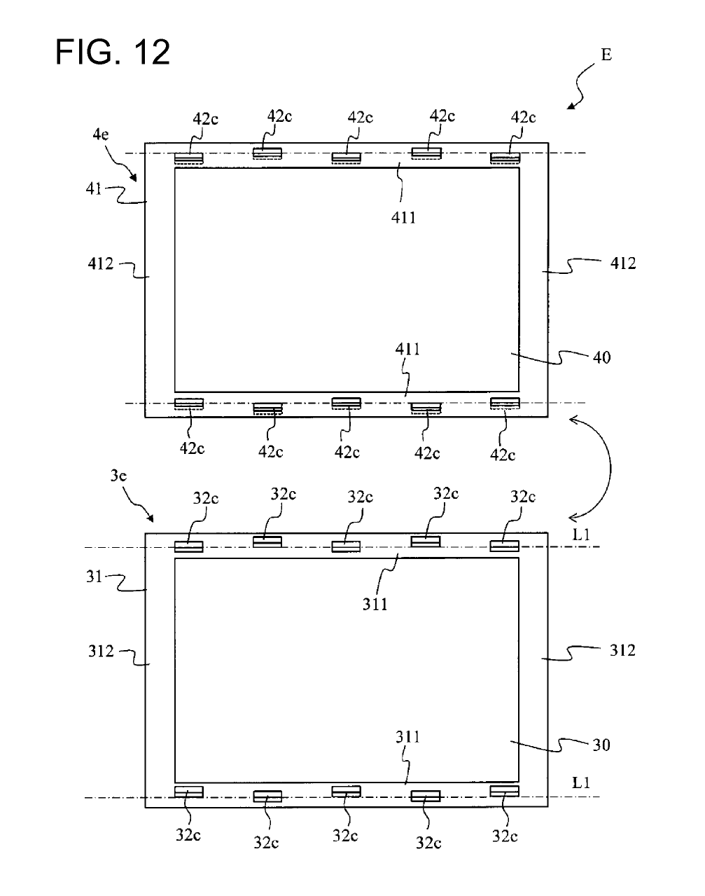

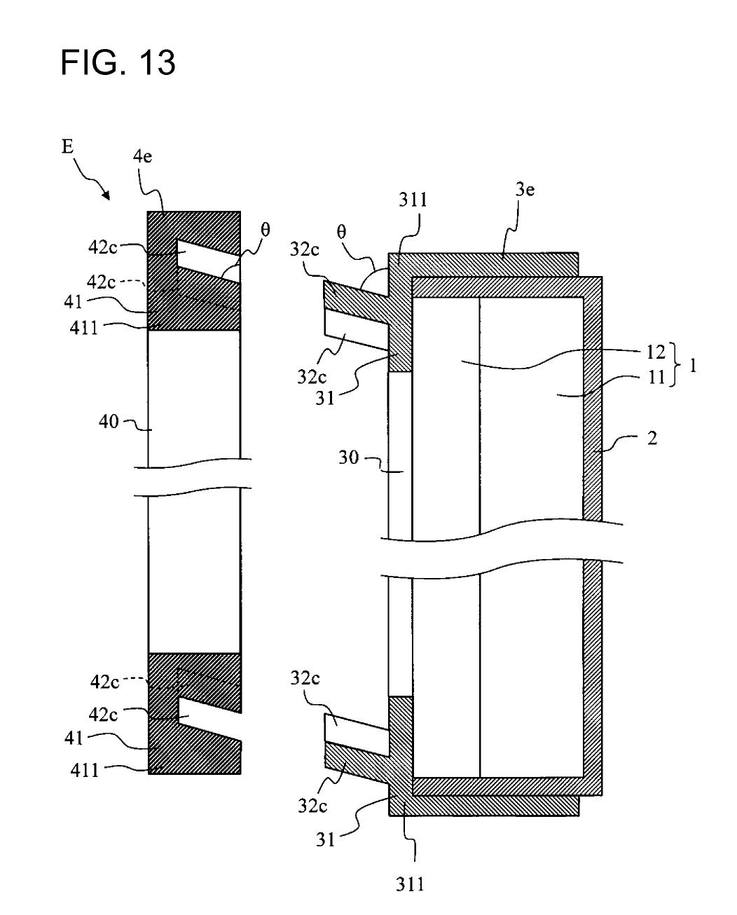

Yet another example of a display device according to the present invention is described, with reference to the drawings. FIG. 12 is a front view of a state in which yet another example of a cover of a display device according to the present invention has been removed, and FIG. 13 is an enlarged cross-sectional view of a state in which the cover of the display device shown in FIG. 12 has been removed. Note that FIG. 12 shows a state in which a cover 4e has been rotated upward and opened, and the cover 4e is flipped upside-down.

In FIG. 12, a display device E according to the present invention has the same configuration as the display device C, aside from an arrangement of engaging protrusions 32c of a cabinet 3e and engaging recesses 42c of the cover 4e differing; substantially identical parts are given the same reference characters, and detailed descriptions of identical parts are omitted. Furthermore, the cover 4e of the display device E shown in FIG. 12 shows a state rotated forward around a top end portion and opened, and in FIG. 12 the cover 4e is flipped upside-down.

As shown in FIG. 12, the cabinet 3e is such that five of the engaging protrusions 32c are formed on both of a pair of long side portions 311 included in the main body 31, arranged in a lengthwise direction of the long side portions 311. The five engaging protrusions 32c are arranged in an alternating fashion on either side of center lines L1 extending along the long side portions 311. Furthermore, as shown in FIG. 12, the engaging protrusions 32c that are provided to the long side portions 311 are all inclined at an angle of inclination 0 in an identical direction (upward in FIG. 12). The engaging protrusions 32c are identical to those provided to the cabinet 3c in the display device C, and therefore a detailed description is omitted.

Furthermore, as shown in FIG. 13, the cover 4e is such that five of the engaging recesses 42c are formed on both of a pair of long side portions 411 included in the main body 41, arranged in a lengthwise direction of the long side portions 411. The five engaging recesses 42c are arranged in an alternating fashion on either side of center lines extending along the long side portions 411. Furthermore, the engaging recesses 42c provided in the long side portions 411 all have an identical direction, that is, an identical direction of inclination and an identical angle of inclination as the engaging protrusions 32c when the cover 4e is attached to the cabinet 3e. Note that the engaging recesses 42c are identical to those provided to the cover 4c of the display device C, and therefore a detailed description is omitted.

In other words, the display device E is configured such that the engaging protrusions 32c that are provided to the two long side portions 311 of the cabinet 3e are inserted into the engaging recesses 42c that are provided in the two long sides 411, the cover 4e thereby being attached to the cabinet 3e. By attaching the cover 4e to the cabinet 3e such that the engaging protrusions 32c are inserted into the engaging recesses 42c, both top-side ones of the long side portions 411 of the cover 4e and bottom-side ones of the long side portions 411 do not readily come off of respectively corresponding ones of the long side portions 311 of the cabinet 3e, thereby making it possible to raise the affixing strength when the cover 4e is attached to the cabinet 3e.

In the present embodiment, the engaging protrusions 32c were formed in the long side portions 311 in the same direction, but a configuration may be used in which a direction is different. For example, the engaging protrusions 32c that are provided to the top-side long side portions 311 may be inclined upward and the engaging protrusions 32c that are provided to the bottom-side long side portions 311 may be inclined downward. Furthermore, the engaging recesses 42c that are provided to the cover 4e are formed in a shape such that the engaging protrusions 32c may respectively be inserted.

In this case, the top-side engaging protrusions 32c and the bottom-side engaging protrusions 32c spread out in mutually-opposing directions, making attachment of the cover 4e difficult as-is. Accordingly, it is also possible for the engaging protrusions 32c and (or) the cover 4 to be formed so as to undergo elastic deformation when the cover 4e is attached, ends of the engaging protrusions 32c thereby being inserted into the corresponding engaging recesses 42c. Specifically, when the cover 4e is attached to the cabinet 3e, the tips of the top-side engaging protrusions 32c are inserted into the top-side engaging recesses 42c.

Then, when a bottom side of the cover 4e is rotated so as to approach the cabinet 3e, the cover 4e is rotated while being pulled downward, the top-side engaging protrusions 32c and (or) the cover 4e are caused to undergo elastic deformation, and the tips of the bottom-side engaging protrusions 32c are inserted into the bottom-side engaging recesses 42c. Thereafter, the cover 4e is rotated towards the cabinet 3e, while weakening a force pulling thereon. The bottom-side engaging protrusions 32c thus protrude in a direction of rotation of the cover 4e, and therefore the bottom-side engaging protrusions 32c proceed into bottoms of the bottom-side engaging recesses 42c even if the force pulling on the cover 4e is weakened.

Specifically, the cover 4e is pulled on only for an instant during which the tips of the bottom-side engaging protrusions 32c are inserted into the bottom-side engaging recesses 42c and the top-side engaging protrusions 32c and (or) the cover 4e are subjected to elastic deformation and thereafter return to original shapes, and therefore the engaging protrusions 32c do not readily come out of the engaging recesses 42c.

Note that it is preferable that the engaging protrusions 32c have an angle of inclination sufficient that the tips are inserted into the engaging recesses 42c when the engaging protrusions 32c and (or) the cover 4e undergo elastic deformation. Note that the angle of inclination of the top-side engaging protrusions 32c and the angle of inclination of the bottom-side engaging protrusions 32c need not necessarily match; it is also possible for a direction of inclination of the top-side engaging protrusions 32c and a direction of inclination of the bottom-side engaging protrusions 32c to be identical, with angles of inclination differing.

Furthermore, in the display device E the top-side engaging protrusions 32c and the bottom-side engaging protrusions 32c are arranged in an alternating manner on either side of a line, but, without being limited to this, it is also possible for at least one set of the engaging protrusions 32c to be disposed above the line, like the engaging protrusions 32. Furthermore, it is also possible for the top-side engaging protrusions 32c and (or) the bottom-side engaging protrusions 32c to be an engaging protrusion (for example like the engaging protrusion 32d ) that is long and extends along the long side portion 311. Note that if the engaging protrusions 32c have the aforementioned shape, the engaging recesses 42c are naturally provided with a shape that allows the respective engaging protrusions 32c to enter.

Furthermore, with the display device E, the engaging protrusions 32c and the engaging recesses 42c are formed on sides that are vertically parallel of the cabinet 3e and the cover 4e (the two long sides in this case), but may also, without being limited to this, be formed on horizontally parallel sides (the short sides in this case), in a case of a configuration with which the cover 4e does not readily come off.

Other features are the same as in the display device A described in Embodiment 1.

### Embodiment 6

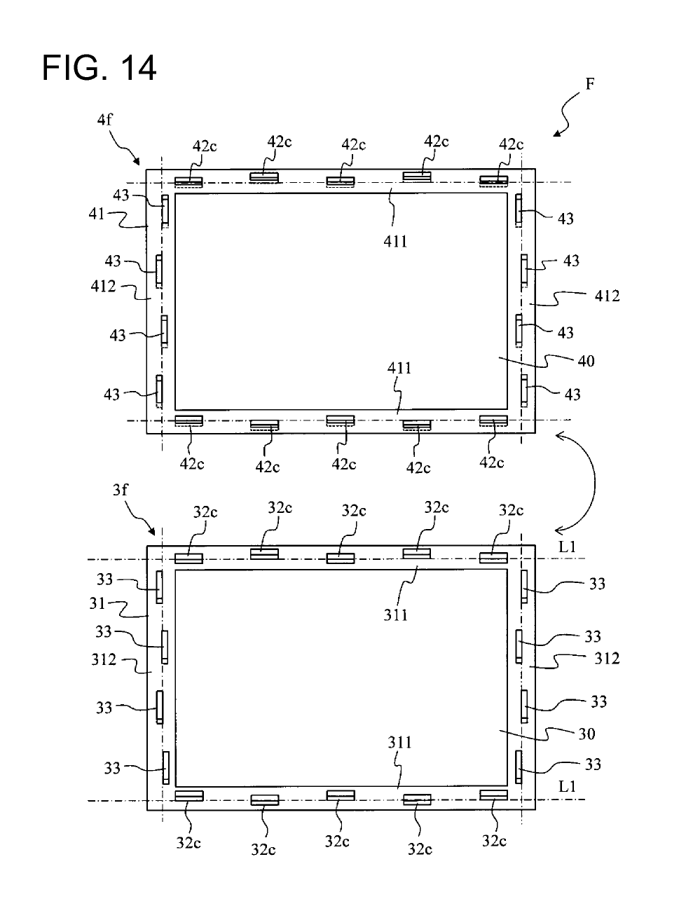

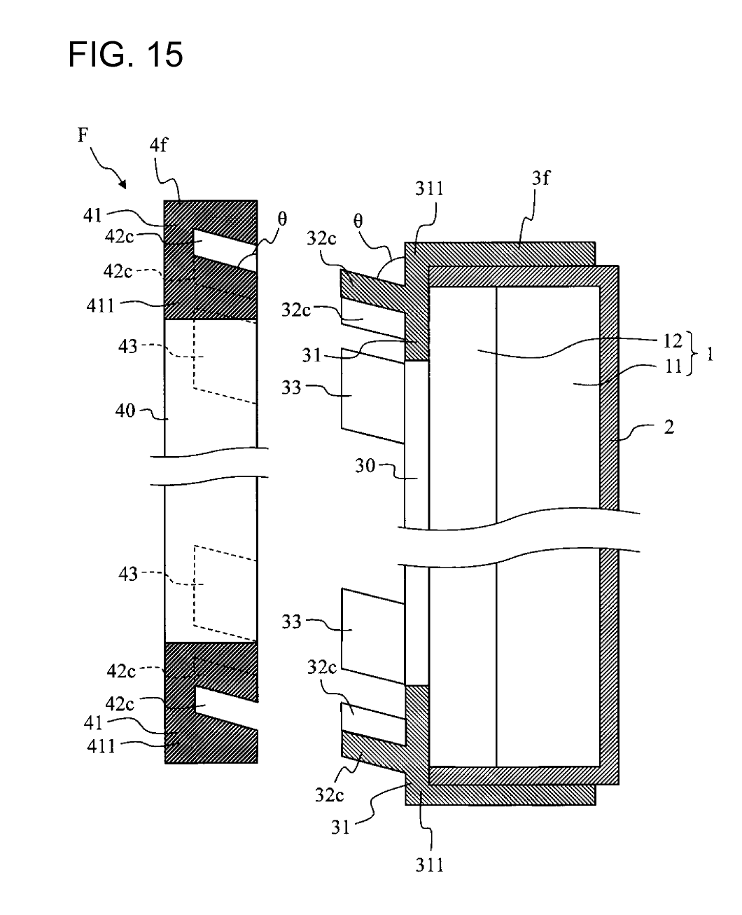

Yet another example of a display device according to the present invention is described, with reference to the drawings. FIG. 14 is a front view of a state in which yet another example of a cover of a display device according to the present invention has been removed, and being a later cross-sectional view of a state in which the cover of the display device shown in FIG. 12 has been removed.

In FIG. 14, a display device F according to the present invention has the same configuration as the display device E, aside from including engaging protrusions 33 that are provided to a cabinet 3f and engaging recesses 43 that are provided to a cover 4f ; substantially identical parts are given the same reference characters, and detailed descriptions of identical parts are omitted. Furthermore, the cover 4f of the display device F shown in FIG. 14 shows a state rotated forward around a top end portion and opened, and in FIG. 14 the cover 4f is flipped upside-down.

As shown in FIG. 14, with the cabinet 3f, five each of engaging protrusions 32c are disposed, arranged along two long side portions 311, respectively, of a main body 31. Four each of the engaging protrusions 33 are disposed, arranged along two short side portions 312, respectively, of the main body 31. The engaging protrusions 32c that are provided to the long side portions 311 are such that tips thereof are inclined upward, and the engaging protrusions 33 that are provided to the short side portions 312 are provided inclined in an identical direction as the engaging protrusions 32c, that is, upward. Note that the engaging protrusions 32c and the engaging protrusions 33 are arranged in an alternating manner on either side of lines along the long side portions 311 and the short side portions 312.

As shown in FIG. 14, with the cabinet 3f, five each of engaging recesses 42c are disposed along two long side portions 411, respectively, of the main body 41. Furthermore, four each of the engaging recesses 43 are arranged on the short side portions 412, respectively. The engaging recesses 42c and the engaging recesses 43 are arranged in an alternating manner on either side of lines along the long side portions 411 and the short side portions 412. When the cover 4f is attached to a front surface of the cabinet 3f, the engaging recesses 42c are formed in positions so as to engage the engaging protrusions 32c and the engaging recesses 43 are formed in positions so as to engage the engaging protrusions 33.

With the display device F, the engaging protrusions 32c that are provided to the two long side portions 311, respectively, of the cabinet 3f and the engaging recesses 42c that are provided to the two long side portions 411, respectively, of the cover 4f engage. Furthermore, the engaging protrusions 33 that are provided to the two short side portions 312 of the cabinet 3f and the engaging recesses 43 that are provided to the two short side portions 412 of the cover 4f engage. By thus attaching the cover 4f to the cabinet 3f, the cabinet 3f does not readily come off of the cover 4f.

Note that with the display device F thus described, the engaging protrusions 32c and the engaging protrusions 33 are inclined in an identical direction (upward), and therefore the cover 4f is attached to the cabinet 3f by being slid in a direction in which the engaging protrusions 32c and the engaging protrusions 33 protrude. Moreover, the cover 4f is pressed downward by a weight of the cover 4f itself, and the engaging protrusions 32c and the engaging protrusions 33 enter into bottoms of the engaging recesses 42c and the engaging recesses 43 and engage. Thus, in a case of the display device F having the aforementioned configuration, the cover 4f can be attached to the cabinet 3f simply, and the cover 4f does not readily come off of the cabinet 3f.

Furthermore, in a case in which the cabinet 3f and the cover 4f are securely affixed by engagement between the engaging protrusions 32c on the top-side long side portions 311 and left and right ones of the short side portions 312 of the cabinet 3f and the engaging recesses 42c of the top-side long side portions 411 and left and right ones of the short side portions 412 of the cover 4f, the engaging protrusions 32c of the bottom-side long side portions 311 of the cabinet 3f and the engaging recesses 42c of the bottom-side long side portions 411 of the cover 4f may be omitted.

Furthermore, a configuration is also possible in which the engaging protrusions 32c of the bottom-side long side portions 311 of the cabinet 3f are inclined downward (inclined towards an outer peripheral side of the cabinet 3f ). Here, the engaging recesses 42c of the bottom-side long side portions 411 of the cover 4f have a shape so as to allow engagement with the engaging protrusions 32c (a shape inclined in a direction allowing engagement).

In a case of such a configuration, when the cover 4f is attached to the cabinet 3f, the cover 4f is attached while being pulled on, like when attaching the cover 4e, thereby making attachment possible while causing the engaging protrusions 32c and (or) the cover 4f to undergo elastic deformation. An affixation strength of the cover 4f attached to the cabinet 3f can thus be raised.

Furthermore, a direction of inclination of the engaging protrusions 33 that are formed in the short side portions 312 of the main body 31 of the cabinet 3f may be perpendicular to the cabinet 3f or towards an outer peripheral side, and not a direction identical to the engaging protrusions 32c. If the engaging protrusions 33 are constituted in this manner, the top-side engaging protrusions 32c and the engaging protrusions 33 that are provided to one of the short side portions 312 are caused to engage the engaging recesses 42c and the engaging recesses 43 when the cover 4f is attached to the cabinet 3f. Furthermore, the cabinet 3f can be attached to the cover 4f by pulling the cover 4f diagonally and causing the bottom-side engaging protrusions 32c and the engaging protrusions 33 that are provided to the other short side portion 312 to engage the engaging recesses 42c and the engaging recesses 43.

Note that it is also possible for a direction of inclination of the top-side engaging protrusions 32c and a direction of inclination of the bottom-side engaging protrusions 32c to be identical and for angles of inclination to differ. Furthermore, similarly, it is also possible for directions of inclination of right-side ones of the engaging protrusions 33 and left-side ones of the engaging protrusions 33 to be opposite, and it is also possible for a direction to be identical and angles of inclination to differ. Here the engaging protrusions 32c and the engaging protrusions 33 are preferably formed so as to easily engage the engaging recesses 42c and the cover 43. For example, an angle of inclination of the engaging protrusions 32c that are provided to a bottom side of the cabinet 3f and the engaging protrusions 33 on a side that the engaging recesses 43 of the cover 4f engage afterward is preferably formed close to perpendicular.

Moreover, in the display device F, the engaging protrusions 32c and the engaging protrusions 33 are arranged in an alternating manner on either side of a line, but, without being limited to this, at least one or another of the engaging protrusions 32c and (or) the engaging protrusions 33 may be arranged in a straight line, like the engaging protrusions 32. Furthermore, it is also possible for the top-side engaging protrusions 32c and (or) the bottom-side engaging protrusions 32c to be an engaging protrusion (for example, similar to the engaging protrusion 32c d) that is long and extends along the long side portion 311. Note that if the engaging protrusions 32c have the aforementioned shape, the engaging recesses 42c are naturally provided with a shape that allows the respective engaging protrusions 32c to enter.

Other features are the same as in the display device A described in Embodiment 6.

### Embodiment 7

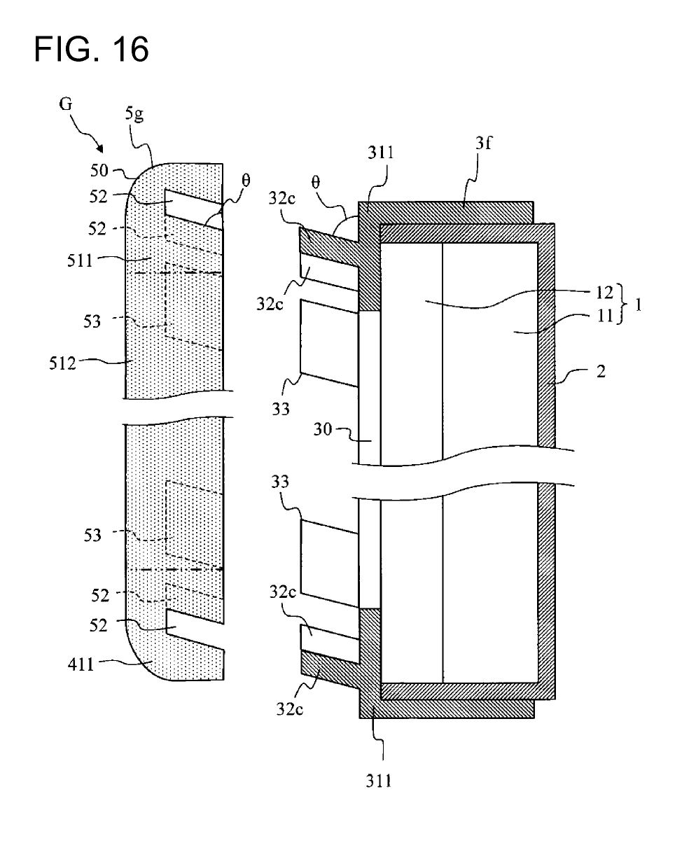

Yet another example of a display device according to the present invention is described, with reference to the drawings. FIG. 16 is a lateral cross-sectional view of a state in which a cover of yet another example of a display according to the present invention has been removed. A display device G as shown in FIG. 16 has an identical configuration as display device F, aside from a cover 5g differing. Because of this, in the display device G as shown in 16, parts that are identical to the display device F are given the same reference characters, and detailed descriptions of identical parts are omitted.

As shown in FIG. 16, the display device G is such that a cover 4g is attached to a front surface side of the cabinet 3f. The cover 5g is a transparent plate-like member, and is constituted so as to be provided with a lens 50 in peripheral edges.

In the display device G, light emitted by the display screen of the display unit 1 is light that diffuses (spreads). Furthermore, this light that spreads passes through an opening 30 in the cabinet 3f and enters the cover 5g. A lens 50 of the cover 5g causes light that is emitted from an end face of the opening 30 to refract so as to face towards the front surface side. By causing refraction in this manner, a main body of the cabinet 3f that is disposed on a rear surface side is made not visible or difficult to see by a viewer with the lens 50 of the cover 5g.

Therefore, with the cover 5g, the lens 50 that is formed on peripheral edges, a frame-shaped attachment portion 51 that is formed on the rear surface side of the lens 50, engaging recesses 52 that are holes provided in long side portions 511 of the attachment portion 51, and engaging recesses 53 that are holes provided in short side portions 512 of the attachment portion 51.

The engaging recesses 52 and the engaging recesses 53 are disposed such that the deepest portions intersect with a light path of light that passes through the lens 50. Furthermore, by inserting engaging protrusions 32c of the cabinet 3f into the engaging recesses 52 and engaging protrusions 33 into the engaging recesses 53, the cover 5g can be affixed securely to the cabinet 3f.

By using the cover 5g having this configuration, a region other than a display region, that is, a frame region, becomes not (or less) visible when the display device G is viewed from the front surface side. Design characteristics of the display device G can thus be improved. Furthermore, because a configuration is used in which the engaging protrusions 32c and the engaging protrusions 33 that protrude towards the front surface side are inserted into and engage the engaging recesses 52 and the engaging recesses 53 that are formed in the attachment portion 51 on a rear side of the cover 5g, the cover 5g can be attached in a stable and secure manner to the cabinet 3f, even if the frame region is small. The lens 50 that has an effect of hiding the frame region can thus be made smaller, and thus it is possible to make the cover 5g more compact and the display device G more compact and thinner.

Other features are the same as in the display device A described in Embodiment 1.

### Other Embodiments

With a display device according to the present invention, a cabinet surrounds a periphery of a display unit and suppresses external shocks from acting on the display unit. Therefore, the cabinet is preferably formed from a material that has high strength. Accordingly, a material formed from aluminum (alloy), stainless steel, steel plate, or another metal material can be used as the material constituting the cabinet.

On the other hand, with a display device according to the present invention, a cover is attached to the cabinet by causing engaging protrusions that are provided to the cabinet to engage engaging recesses in the cover. Furthermore, with the display device, an amount of heat emitted by a display unit, etc., is large, and the cabinet and the cover sometimes reach high temperatures. In such cases, if there is a large discrepancy between coefficients of linear expansion between the cabinet and the cover, stress (heat stress) tends to focus on the engaging protrusions due to a discrepancy in thermal expansion, which can become a cause of breakage.

The cover is a portion with which a user tends to come in contact, and a resin that has low heat conductivity is used, and not a metal that can reach high temperatures. Furthermore, to prevent generation of heat stress in the engaging protrusions, a resin that is identical to the cover or a resin having a similar coefficient of linear expansion is used in the cabinet as well. Note that polycarbonate (PC: coefficient of linear expansion, 7×10⁻⁵ [cm/cm·° C.]), ABS resin (coefficient of linear expansion, 7×10⁻⁵-13×10⁻⁵ cm/cm·° C.]), or a polymer alloy of polycarbonate and ABS resin (coefficient of linear expansion, 7×10⁻⁵ [cm/cm·° C.]), etc., can be used, for example, as the resin used in the cover. Furthermore, even in a case in which a resin other than these is used, breakage due to heat stress can be suppressed by using a resin such that the coefficients of linear expansion between the cover and the cabinet do not significantly differ or are identical.

In the above embodiments, the engaging protrusions are provided on the cabinet and the engaging protrusions are formed in the cover, but, conversely, a configuration is also possible in which the engaging protrusions are provided on the cover and the engaging recesses are provided in the cabinet. In this case, when the cover is attached to the cabinet, the engaging protrusions are inclined upwards towards the front surface side or towards an outer peripheral side. Therefore, in the cover, the engaging recesses are inclined with a protruding tip end side as an inner peripheral side.

Furthermore, in the above embodiments, a display unit that displays an image to a front surface side is included as an example of a display device (for example, a liquid crystal display unit, an EL display unit, etc.), but the display device can also be used as an illumination device by using a device configured to emit planar light as this display unit (such as a light-emitting configuration that preferably emits a planar light flux with uniform brightness).

Embodiments of the present invention have been described above, but the present invention is not limited to this content. Furthermore, various modifications can be applied to embodiments of the present invention as long as the modifications do not depart from the gist of the invention.

### INDUSTRIAL APPLICABILITY

The present invention can be used to affix a cabinet to a cover of a display device that displays an image, such as a liquid crystal television, a liquid crystal display device, or the like, an illumination device that emits planar light in which a light flux density is uniform, and the like.

### DESCRIPTION OF REFERENCE CHARACTERS

A to G display device
display unit
   chassis
      3, 3b to 3f cabinet

30 opening

31 main body

311 long side portions

312 short side portions

32, 32b to 32d engaging protrusions

4, 4b to 4g cover

40 opening

41 main body

411 long side portions

412 short side portions

5g cover

50 lens

51 attachment portion

511 long side portions

512 short side portions

52 engaging recesses

53 engaging recesses

1. A display device, comprising:
a first cover member having a first frame configured to surround a periphery of a front surface of a display unit;
a second cover member having a second frame disposed on a front surface side of the first cover member and overlapping the first frame;
an engaging protrusion that protrudes from a front surface of the first frame or a rear surface of the second frame; and
an engaging recess formed in the first frame or the second frame that does not have the engaging protrusion, said engaging recess being formed in a surface that faces the front surface of the first frame or the rear surface of the second frame where said engaging protrusion is protruding, said engaging protrusion engaging said engaging recess.

2. The display device according to claim 1, wherein the engaging protrusion is provided in a plurality in a straight line on a periphery of the first frame or the second frame.

3. The display device according to claim 1, wherein the engaging protrusion is provided in a plurality in a generally straight line and shifted in position in a direction orthogonal to an arrangement direction thereof.

4. The display device according to claim 1, wherein the engaging protrusion is inclined with respect to a surface from which said engaging protrusion protrudes.

5. The display device according to claim 1,
wherein the engaging protrusion has, at a tip thereof, a curved portion that curves outward, and
wherein the engaging recess has a fitting portion in which said curved portion fits

6. The display device according to claim 1,
wherein the first frame and the second frame are each a rectangular frame, and
wherein the engaging protrusion is formed on at least two of four sides of the first frame or the second frame.

7. The display device according to claim 1,
wherein the first cover member is a bezel configured to hold the display unit, and
wherein the second cover member is a lens cover having a lens on side edges thereof.

8. The display device according to claim 1, wherein the display unit is a light-emitting unit that emits planar light from a front surface thereof.

9. The display device according to claim 2, wherein the engaging protrusion is inclined with respect to a surface from which said engaging protrusion protrudes.

10. The display device according to claim 3, wherein the engaging protrusion is inclined with respect to a surface from which said engaging protrusion protrudes.

11. The display device according to claim 2,
wherein the engaging protrusion has, at a tip thereof, a curved portion that curves outward, and
wherein the engaging recess has a fitting portion in which said curved portion fits.
